(19) United States
(12) Patent Application Publication
(10) Pub. No.: US 2018/0152016 A1
(43) Pub. Date: May 31, 2018

(54) SUPERCONDUCTIVE WIRE AND CURRENT LIMITER

(71) Applicant: SUMITOMO ELECTRIC INDUSTRIES, LTD., Osaka-shi, Osaka (JP)

(72) Inventors: Yoshihiro HONDA, Osaka-shi, Osaka (JP); Shigeki ISOJIMA, Osaka-shi, Osaka (JP)

(73) Assignee: SUMITOMO ELECTRIC INDUSTRIES, LTD., Osaka-shi, Osaka (JP)

(21) Appl. No.: 15/570,825

(22) PCT Filed: Jul. 1, 2016
(86) PCT No.: PCT/JP2016/069698

§ 371 Date: Oct. 31, 2017

(30) Foreign Application Priority Data
Jul. 16, 2015 (JP) 2015-142030

(51) Int. Cl. H02H 9/02; H01L 39/16; H01L 39/24; H02H 7/00; H01B 12/16; H01F 6/04; H01F 6/02

(52) U.S. Cl. CPC H02H 9/023; H01L 39/16; H01L 39/24; H01F 6/02; H01B 12/16; H01F 6/04; H02H 7/001

(57) ABSTRACT

Provided is a superconductive wire comprising: a superconductive wire core which has a first main surface extending in the longitudinal direction and a second main surface located on the side opposite to the first main surface; a first heat dissipation member disposed on the first main surface; and a second heat dissipation member disposed on the second main surface. The first heat dissipation member is connected to the first main surface at a plurality of first connection locations lined up along the longitudinal direction. The second heat dissipation member is connected to the second main surface at a plurality of second connection locations lined up along the longitudinal direction. In the planar view from the thickness direction of the superconductive wire, each of the plurality of first connection locations and a corresponding one of the plurality of second connection locations are arranged with an offset from each other.

### TECHNICAL FIELD

The present disclosure relates to a superconductive wire and a current limiter.

The present application claims the priority to Japanese patent application No. 2015-142030 filed on Jul. 16, 2015, the contents of which are incorporated herein by reference in their entirety.

### BACKGROUND ART

A current limiter using a superconductor is known (for example, see Japanese Patent Laying-Open No. 2-159927 (PTD 1).

### CITATION LIST

### Patent Document

PTD 1: Japanese Patent Laying-Open No. 2-159927

### SUMMARY OF INVENTION

A superconductive wire of the present disclosure includes: a superconductive wire core which has a first main surface extending in the longitudinal direction and a second main surface located on the side opposite to the first main surface and extending in the longitudinal direction; a first heat dissipation member disposed on the first main surface; and a second heat dissipation member disposed on the second main surface. The first heat dissipation member is connected to the first main surface at a plurality of first connection locations which are lined up along the longitudinal direction. The second heat dissipation member is connected to the second main surface at a plurality of second connection locations which are lined up along the longitudinal direction. In the planar view from the thickness direction of the superconductive wire, each of the plurality of first connection locations and a corresponding one of the plurality of second connection locations are arranged with an offset from each other.

### BRIEF DESCRIPTION OF DRAWINGS

FIG. 1 is a schematic view illustrating the structure of a current limiter according to a first embodiment;

FIG. 2 is a schematic view illustrating the structure of a coolant container configured to house therein a superconductive unit of the current limiter illustrated in FIG. 1;

FIG. 3 is an enlarged view of the superconductive unit illustrated in FIG. 2, in which a superconductive coil constituting the superconductive unit is schematically illustrated in cross-sectional view;

FIG. 4 is a schematic cross-sectional view illustrating the structure of the superconductive wire illustrated in FIG. 3;

FIG. 5 is an enlarged partial view of the superconductive wire illustrated in FIG. 4;

FIG. 6 is a schematic cross-sectional view illustrating an exemplary structure of the superconductive member illustrated in FIG. 4;

FIG. 7 is a schematic cross-sectional view illustrating the structure of a superconductive wire according to a first modification of the first embodiment;

FIG. 8 is a schematic cross-sectional view illustrating the structure of a superconductive wire according to a second modification of the first embodiment;

FIG. 9 is a schematic perspective view illustrating the structure of a superconductive wire according to a second embodiment;

FIG. 10 is a schematic cross-sectional view illustrating the structure of the superconductive wire illustrated in FIG. 8;

FIG. 11 is a schematic perspective view illustrating the structure of a superconductive wire according to a first modification of the second embodiment;

FIG. 12 is a schematic planar view illustrating a superconductive wire according to a second modification of the second embodiment;

FIG. 13 is a schematic cross-sectional view illustrating the structure of a superconductive wire according to a third embodiment;

FIG. 14 is a schematic cross-sectional view illustrating the structure of a superconductive wire according to a first modification of the third embodiment;

FIG. 15 is a schematic cross-sectional view illustrating the structure of a superconductive wire according to a second modification of the third embodiment;

FIG. 16 is a schematic cross-sectional view illustrating the structure of a superconductive wire according to a fourth embodiment;

FIG. 17 is a schematic cross-sectional view illustrating the structure of a superconductive wire according to a first modification of the fourth embodiment; and

FIG. 18 is a schematic cross-sectional view illustrating the structure of a superconductive wire according to a second modification of the fourth embodiment.

### DESCRIPTION OF EMBODIMENTS

In PTD 1, a current limiting element for suppressing a short-circuit current is made of a superconductor which becomes superconductive at a temperature equal to or lower than the liquid nitrogen temperature. The current limiting element is disposed in liquid nitrogen, and when a short-circuit fault occurs in a power transmission system where a current limiter is installed, a short-circuit current exceeding the critical current flows through the current limiting element, which causes the current limiting element to transfer from the superconductive state to the normal conductive state and become a resistor so as to the short-circuit current.

When a short-circuit current flows through the current limiting element, the current limiting element generates heat, and thereby the temperature of the current limiting element rises. In a power transmission system where the current limiter is installed, when the short-circuit state is restored immediately after a short circuit such as an instantaneous short circuit, it is required that the current limiting element be quickly restored to the normal state (in other words, the superconductor is required to restore from the normal conductive state to the superconductive state) after the short-circuit current is blocked.

However, when the current capacity of a current limiting element is increased so as to cope with a larger short-circuit current, since the short-circuit current flowing through the superconductor is larger than that of the conventional current limiter, it makes the superconductor to generate more heat, and as a result, the temperature of the superconductor becomes excessively high.

When the temperature of the superconductor rises, the temperature of a coolant (for example, liquid nitrogen) for cooling the superconductor also rises and reaches a boiling state. When the heat flux from the superconductor is weak, the boiling state of the coolant remains at a nucleate boiling state where small bubbles are generated continuously; however, as the heat flux becomes greater than a critical heat flux for nucleate boiling, the boiling state changes to a film boiling state. In the film boiling state, the superconductor is being covered by a film of big bubbles (gaseous coolant), and thereby, the heat is prevented from being transferred from the superconductor to the surrounding coolant by the bubbles. As a result, the cooling speed of the superconductor by the coolant is lowered in comparison with that in the nuclear boiling state, and thereby, a longer time is required to restore the current limiter to the superconductive state.

In addition, after the boiling state of the coolant reaches the film boiling state, in order to lower the temperature of the coolant so as to turn (change) the coolant from the film boiling state to the nucleate boiling state, it is necessary for the coolant to pass through Leidenfrost point where the heat flux has a minimum value, and thus the heat flux further decreases temporarily (in other words, the cooling speed further decreases), which also delays the restoration of the fault current limiter to the superconductive state.

Thus, it is an object of the present disclosure to provide a current limiter using a superconductive wire which capable of increasing the current capacity of the superconductive wire while shortening a time needed to restore the superconductive wire back to the superconductive state.

### Description of Embodiments of the Present Disclosure

Firstly, the embodiments of the present disclosure are listed and described.

(1) A superconductive wire according to one aspect of the present disclosure includes: a superconductive wire core (11) which has a first main surface (11A) extending in the longitudinal direction and a second main surface (11B) located on the side opposite to the first main surface and extending in the longitudinal direction; a first heat dissipation member (12a) disposed on the first main surface; and a second heat dissipation member (12b) disposed on the second main surface. The first heat dissipation member is connected to the first main surface at a plurality of first connection locations which are lined up along the longitudinal direction. The second heat dissipation member is connected to the second main surface at a plurality of second connection locations which are lined up along the longitudinal direction. In a planar view from the thickness direction of the superconductive wire, each of the plurality of first connection locations and a corresponding one of the plurality of second connection locations are arranged with an offset from each other.

According to the abovementioned configuration, in the current limiter using the superconductive wire, the first dissipation member and the second heat dissipation member are disposed on both main surfaces of the superconductive wire core, and when the coolant boils on a surface of the superconductive wire due to the temperature rise of the superconductive wire core during the current limiting operation, the first dissipation member and the second heat dissipation member each functions as a suppression element to prevent the boiling state of the coolant to change from the nucleate boiling state to the film boiling state. Thus, the heat flux transferred from the superconductive wire core to the coolant may be reduced, and as a result, the heat generated at the superconductive wire core during the current limiting operation may be efficiently dissipated to the coolant through the first heat dissipation member and the second heat dissipation member.

On the other hand, due to a conductive connection layer formed at each connection location between the superconductive wire core and the first dissipation member and a conductive connection layer formed at each connection location between the superconductive wire core and the second heat dissipation member, the amount of temperature rises differently at each connection location and the other locations. As a result, when the short-circuit current flowing through the superconductive wire core becomes larger, the temperature of the superconductive wire core locally rises, which makes it difficult to cool down the entire superconductive wire core uniformly and efficiently.

According to the abovementioned configuration, the first connection location and the second connection location are arranged with an offset from each other in the planar view, which makes it possible to reduce the irregular temperature distribution in the entire superconductive wire core. Thus, even when the current capacity of the superconductive wire core is increased, the current limiter may be restored to the superconductive state quickly.

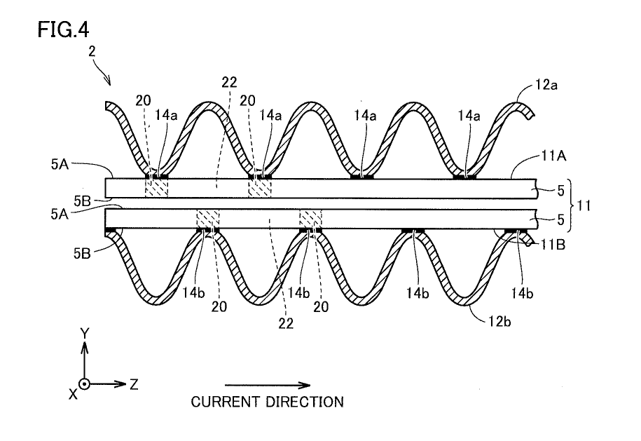

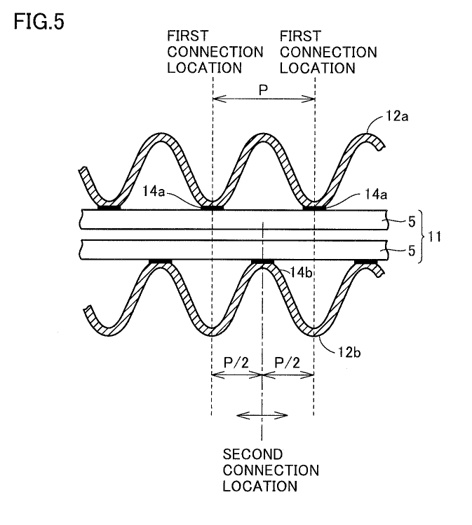

(2) Preferably, in the planar view, the first connection location and the second connection location are arranged with an offset from each other in the longitudinal direction (for example, see FIG. 4). Preferably, when the distance between two of the adjacent first connection locations in the longitudinal direction is denoted by P (see FIG. 5), the second connection location is disposed at a position less than P/2 from the middle point of each of the two adjacent first connection locations. In the planar view, the distance between the second connection location and the middle point is preferably 0.4P or less, and more preferably is 0.3P or less.

According to the abovementioned configuration, it is possible to reduce the irregular temperature distribution in the entire superconductive wire core which is caused by the connection of the first dissipation member and the second heat dissipation member. Accordingly, even when the current capacity of the superconductive wire core is increased, the current limiter may be quickly restored to the superconductive state.

(3) Preferably, the first heat dissipation member and the second heat dissipation member each includes a corrugated plate structure in which a plurality of ridges and a plurality of valleys each extend along the width direction of the superconductive wire core (see FIG. 4). Each of the plurality of valleys of the corrugated plate structure in the first heat dissipation member is connected to the first main surface at a corresponding one of the plurality of first connection locations, and each of the plurality of ridges of the corrugated plate structure in the second heat dissipation member is connected to the second main surface at a corresponding one of the plurality of second connection locations. In the planar view, each of the plurality of valleys in the first heat dissipation member is overlapped with a corresponding one of the plurality of valleys in the second heat dissipation member, and each of the plurality of ridges in the first heat dissipation member is overlapped with a corresponding one of the plurality of ridges in the second heat dissipation member.

According to the abovementioned configuration, even when the first heat dissipation member and the second heat dissipation member, each includes a corrugated plate structure, are respectively connected to both main surfaces of the superconductive wire core, it is possible to reduce the irregular temperature distribution in the entire superconductive wire core.

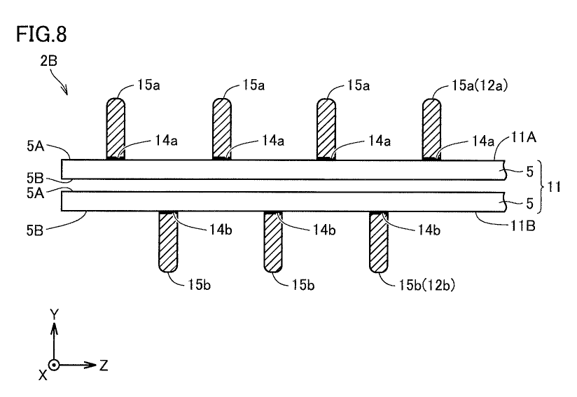

(4) Preferably, the first heat dissipation member is formed by arranging a plurality of first plate-shaped members (15a) extending in the width direction of the superconductive wire core on the first main surface with an interval present therebetween along the longitudinal direction, and the second heat dissipation member is formed by arranging a plurality of second plate-shaped members (15b) extending in the width direction of the superconductive wire core on the second main surface with an interval present therebetween along the longitudinal direction (see FIG. 8). Each of the plurality of first plate-shaped members is connected to the first main surface at a corresponding one of the plurality of first connection locations, and each of the plurality of second plate-shaped members is connected to the second main surface at a corresponding one of the plurality of second connection locations.

According to the abovementioned configuration, when the first heat dissipation member and the second heat dissipation member, each is formed from a plurality of plate-shaped members, are respectively connected to both main surfaces of the superconductive wire core, it is possible to reduce the irregular temperature distribution in the entire superconductive wire core.

(5) Preferably, in the planar view, each of the plurality of first connection locations and a corresponding one of the plurality of second connection locations are arranged with an offset from each other in the width direction of the superconductive wire core.

According to the abovementioned configuration, it is possible to reduce the irregular temperature distribution in the entire superconductive wire core which is caused by the connection of the first dissipation member and the second heat dissipation member. Accordingly, even when the current capacity of the superconductive wire core is increased, the current limiter may be quickly restored to the superconductive state.

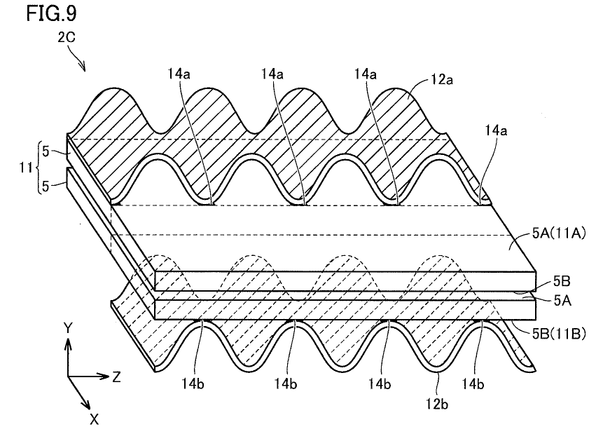

(6) Preferably, the first heat dissipation member and the second heat dissipation member each includes a corrugated plate structure in which a plurality of ridges and a plurality of valleys each extend along the width direction of the superconductive wire core (see FIG. 9). The length of the corrugated plate structure in the width direction of the superconductive wire core is less than the length of the superconductive wire core in the width direction thereof. Each of the plurality of valleys of the corrugated plate structure in the first heat dissipation member is connected to the first main surface at a corresponding one of the plurality of first connection locations in a region located at one side of the first main surface in the width direction, and each of the plurality of ridges of the corrugated plate structure in the second heat dissipation member is connected to the second main surface at a corresponding one of the plurality of second connection locations in a region located at the other side of the second main surface in the width direction which is opposite to the region located at one side of the first main surface in the width direction.

According to the abovementioned configuration, when the first heat dissipation member and the second heat dissipation member, each includes a corrugated plate structure, are respectively connected to both main surfaces of the superconductive wire core, it is possible to reduce the irregular temperature distribution in the entire superconductive wire core.

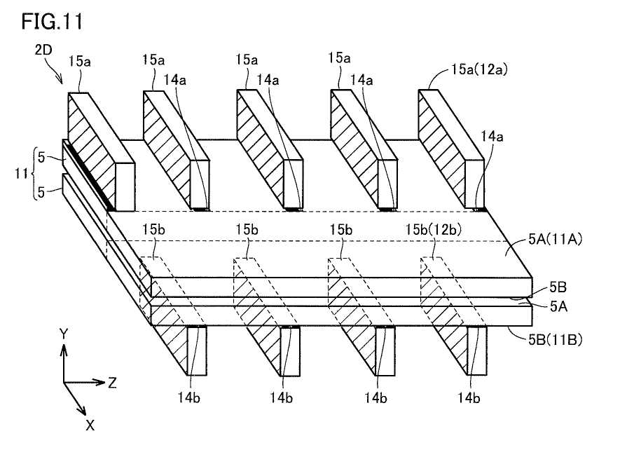

(7) Preferably, the first heat dissipation member is formed by arranging a plurality of first plate-shaped members extending in the width direction of the superconductive wire core on the first main surface with an interval present therebetween along the longitudinal direction, and the second heat dissipation member is formed by arranging a plurality of second plate-shaped members extending in the width direction of the superconductive wire core on the second main surface with an interval present therebetween along the longitudinal direction (see FIG. 11). The length of each of the first plate-shaped member and the length of the second plate-shaped member in the width direction of the superconductive wire core is less than the length of the superconductive wire core in the width direction thereof. Each of the plurality of first plate-shaped members is connected to the first main surface at a corresponding one of the plurality of first connection locations in a region located at one side of the first main surface in the width direction, and each of the plurality of second plate-shaped members is connected to the second main surface at a corresponding one of the plurality of second connection locations in a region located at the other side of the second main surface in the width direction which is opposite to the region located at one side of the first main surface in the width direction.

According to the abovementioned configuration, when the first heat dissipation member and the second heat dissipation member, each is formed from a plurality of plate-shaped members, are respectively connected to both main surfaces of the superconductive wire core, it is possible to reduce the irregular temperature distribution in the entire superconductive wire core.

(8) Preferably, in the planar view, each of the plurality of first connection locations and a corresponding one of the plurality of second connection locations are arranged with an offset from each other in the longitudinal direction.

According to the abovementioned configuration, it is possible to efficiently reduce the irregular temperature distribution in the entire superconductive wire core which is caused by the connection of the first dissipation member and the second heat dissipation member.

(9) Preferably, the superconductive wire further includes a conductive connection layer (14a, 14b) formed between the first heat dissipation member and the superconductive wire core and between the second heat dissipation member and the superconductive wire at each of the plurality of first connection locations and each of the plurality of second connection locations.

According to the abovementioned configuration, it is possible to reduce the irregular temperature distribution in the entire superconductive wire core which is caused by the connection layer formed at each of the plurality of first connection locations and each of the plurality of second connection locations.

(10) Preferably, the superconductive wire core is formed by laminating a plurality of superconductive members (5), each of which has a main surface extending in the longitudinal direction, along the normal direction of the main surface.

According to the abovementioned configuration, even when the current capacity of the superconductive wire core is increased, the heat generated in the superconductive wire core during the current limiting operation may be efficiently dissipated to the coolant through the first dissipation member and the second heat dissipation member, which makes it possible to quickly restore the current limiter to the superconductive state.

(11) Preferably, the current limiter includes a superconductive unit (1) made of the superconductive wire according to any of the above (1) to (10), and a coolant container (30) configured to house therein the superconductive unit and coolant (34) for cooling the superconductive unit.

According to the abovementioned configuration, even when the current capacity of the superconductive wire core is increased, it is possible to quickly restore the current limiter to the superconductive state.

### Details of Embodiments of the Present Disclosure

Hereinafter, embodiment of the present disclosure will be described with reference to the drawings. In the following drawings, the same or corresponding parts will be given the same reference numerals and will not be described repeatedly.

### First Embodiment

(Structure of Current Limiter)

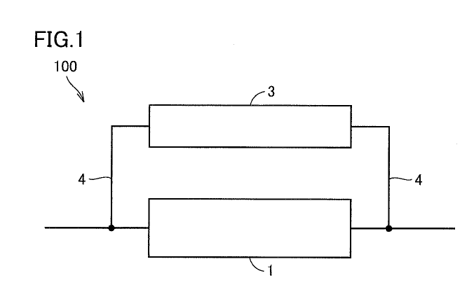

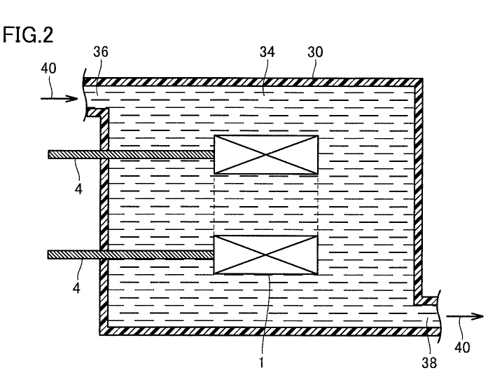

FIG. 1 is a schematic view illustrating the structure of a current limiter according to a first embodiment. FIG. 2 is a schematic view illustrating the structure of a coolant container configured to house therein a superconductive unit of the current limiter illustrated in FIG. 1. A current limiter 100 according to the first embodiment is installed in a power system, for example, and is configured to perform a current limiting operation when a fault such as a short circuit occurs in the power system.

As illustrated in FIG. 1, the current limiter 100 includes a superconductive unit 1 and a parallel resistance unit (or a parallel inductance unit) 3 which are electrically connected in parallel by conductive wires 4.

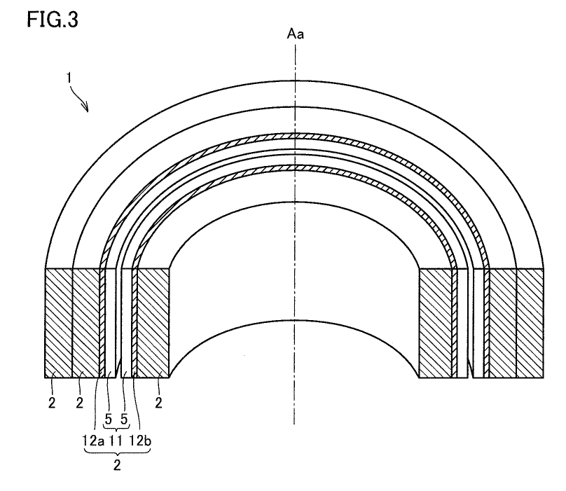

As illustrated in FIG. 3, the superconductive unit 1 includes a superconductive wire 2. Specifically, the superconductive unit 1 includes a superconductive coil made of, for example, the superconductive wire 2. As illustrated in FIG. 2, the superconductive unit 1 is housed in a coolant container 30. The conductive wire 4 penetrates the coolant container 30 and is electrically connected to the superconductive coil. The superconductive unit 1 exhibits a superconductive phenomenon at a critical temperature or lower.

The coolant container 30 is provided with an introduction unit 36 for supplying a coolant 34 flowing through the inside of the coolant container 30, and a discharge unit 38 for discharging the supplied coolant 34 outside of the coolant container 30. As illustrated by an arrow 40, the coolant 34 introduced from the introduction unit 36 into the coolant container 30 absorbs heat generated from the superconductive wire 2 constituting the superconductive unit 1.

As illustrated by another arrow 40, the coolant 34 discharged from the discharge unit 38 to the outside is cooled by a heat exchanger (not shown) or the like, and then supplied back to the introduction unit 36 by a pump (not shown) or the like. In this way, the coolant 34 is housed in a closed path including the coolant container 30, being circulated in the closed path. Alternatively, the coolant 34 is housed in the coolant container 30 without being circulated, and a heat exchange head is inserted into the coolant container 30 from the outside so as to cool down the coolant 34 through heat exchange.

When the current limiter 100 having the abovementioned configuration is put into normal operation, the superconductive unit 1 is cooled down to a cryogenic temperature equal to or lower than the critical temperature according to the heat exchange with the coolant 34 and is thereby maintained at the superconductive state. Thus, in a parallel circuit composed of the superconductive unit 1 and the parallel resistance unit 3, the current will flow through the superconductive unit 1 since it has no electrical resistance.

On the other hand, when a fault occurs in the power system to which the current limiter 100 is connected, an excessive fault current resulted from the fault may cause the superconductive unit 1 to lose its superconductive ability (quench), and thereby, the superconductive unit 1 is shifted to the normal conductive state. Thus, the superconductive unit 1 becomes electrically resistant and autonomously performs the current limiting operation, the current will flow through both the superconductive unit 1 and the parallel resistance unit 3.

During the current limiting operation, the superconductive unit 1 becomes electrically resistant and when the current flows through the superconductive unit 1, the temperature of the superconductive unit 1 will rise rapidly. After the current limiting operation is performed in the current limiter, it is necessary to restore the current limiter to its normal state as early as possible. In other words, the superconductive unit 1 is required to restore from the normal conductive state to the superconductive state.

On the other hand, in order to make the current limiter provide greater current capacity, it is often to increase the cross-sectional area of the superconductive wire. As a result, the short-circuit current flowing through the superconductive unit during the current limiting operation is larger than the short-circuit current flowing through the superconductive unit in a conventional current limiter, the amount of generated joule heat becomes relatively larger. Thereby, a longer time is required to cool down the superconductive unit, which makes it difficult to quickly restore the current limiter back to the superconductive state after the current limiting operation.

In order to improve the cooling capacity of the superconductive unit 1, the current limiter 100 according to the first embodiment is provided with a superconductive wire structurally configured to efficiently dissipate heat generated in the superconductive wire.

The structure of the superconductive wire according to the first embodiment will be described in detail below.

(Structure of Superconductive Wire)

FIG. 3 is an enlarged partial view of the superconductive unit 1 illustrated in FIG. 2, in which a superconductive coil constituting the superconductive unit is schematically illustrated in cross-sectional view. As illustrated in FIG. 3, the superconductive coil constituting the superconductive unit 1 is formed by winding the superconductive wire 2, which has an elongated rectangular shape (tape shape) in cross section, around a winding shaft Aa. The superconductive coil may be formed by spirally winding the superconductive wire 2 around the winding shaft Aa. Alternatively, the superconductive coil may be formed by laminating a plurality of pancake coils. In such a case, the direction of the winding shaft Aa is identical to the laminating direction of the plurality of pancake coils.

The superconductive coil represents an example of the “superconductive unit” in the present disclosure. The superconductive 1 is not limited to a superconductive coil, and may be formed from the superconductive wire 2 that is not wound.

The superconductive wire 2 includes a tape-shaped superconductive wire core 11, a first heat dissipation member 12a and a second heat dissipation member 12b. In FIG. 3, the superconductive wire core 11 is formed by laminating a plurality of (for example, two pieces of) superconductive members 5. The first heat dissipation member 12a is disposed on one main surface of the superconductive wire core 11, and the second heat dissipation member 12b is disposed on the other main surface of the superconductive wire core 11. The length of the superconductive wire core 11 in the width direction is, for example, about 4 mm. The thickness of the superconductive wire core 11 is, for example, about 0.1 mm. The thickness of each of the first heat dissipation member 12a and the second heat dissipation members 12b is, for example, about 0.1 mm.

FIG. 4 is a schematic cross-sectional view illustrating the structure of the superconductive wire illustrated in FIG. 3. The cross section illustrated in FIG. 4 is cut along the extending direction of the superconductive wire 2. Thus, the lateral direction of the paper is taken as the longitudinal direction of the superconductive wire 2, and the current flows along the lateral direction of the paper. The vertical direction of the paper is taken as the thickness direction of the superconductive wire 2, and the direction perpendicular to the paper is taken as the width direction of the superconductive wire 2. Furthermore, in the schematic cross-sectional view of FIG. 4 and the following figures, the longitudinal direction of the superconductive wire 2 is denoted by Z, the width direction of the superconductive wire 2 is denoted by X, and the thickness direction of the superconductive wire 2 is denoted by Y.

As illustrated in FIG. 4, the superconductive wire core 11 is formed into a tape shape having a rectangular cross section, and a relatively large surface of the tape extending in the longitudinal direction is defined as the main surface. The superconductive wire core 11 includes a first main surface 11A, and a second main surface 11B located on the side opposite to the first main surface 11B.

The superconductive wire core 11 is formed by laminating 2 pieces of the superconductive members 5, each has a main surface extending in the longitudinal direction, along the normal direction of the main surface. The superconductive member 5 used to form the superconductive wire core 11 may be 1 or at least 3. When the superconductive wire core 11 is formed by laminating a plurality of superconductive members 5, the main surfaces of the adjacent superconductive members 5 facing each other may be joined to each other directly, or may be bonded to each other by using a conductive bonding agent such as solder or a conductive adhesive. Alternatively, the main surfaces facing each other may be bonded to each other by using a bonder made of an electrically insulating material.

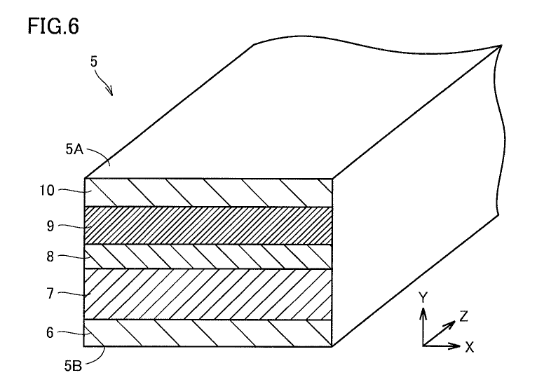

As the superconductive member 5, for example, a thin film-based superconductive wire (see FIG. 6) having a high electrical resistance value at room temperature may be adopted, and alternatively, a bismuth-based silver sheathed superconductive wire may be adopted as long as it can achieve an electrical resistance required by a current limiter at room temperature.

FIG. 6 is a schematic cross-sectional view illustrating an exemplary structure of the superconductive member 5 illustrated in FIG. 4. The cross section illustrated in FIG. 6 is cut along a direction perpendicular to the extending direction of the superconductive member 5. Thus, the direction perpendicular to the paper is taken as the longitudinal direction of the superconductive member 5, the lateral direction of the paper is taken as the width direction of the superconductive member 5, and the vertical direction of the paper is taken as the thickness direction of the superconductive member 5.

As illustrated in FIG. 6, a thin film-based superconductive wire which is formed into a tape shape and has a rectangular cross section may be used as the superconductive member 5. The superconductive member 5 has a main surface 5A, and a main surface 5B located on the side opposite to the main surface 5A. The superconductive member 5 includes a substrate 7, an intermediate layer 8, a superconductive layer 9, and stabilization layers 6 and 10.

As the substrate 7, for example, an oriented metal substrate in which metal crystals are uniformly orientated in 2 in-plane axial directions of the substrate surface may be adopted. As the oriented metal substrate, any alloy made of at least 2 kinds of metals selected from nickel (Ni), copper (Cu), chromium (Cr), manganese (Mn), cobalt (Co), iron (Fe), palladium (Pd), silver (Ag), and gold (Au) may be used appropriately. It is acceptable that these metals may be laminated with other metals or alloys, and a high-strength alloy such as SUS alloy may be used.

The intermediate layer 8 is formed on the main surface of the substrate 7. The superconductive layer 9 is formed on one main surface of the intermediate layer 8 opposite to the main surface facing the substrate 7. As materials for forming the intermediate layer 8, yttria stabilized zirconia (YSZ), cerium oxide (CeO₂), magnesium oxide (MgO), yttrium oxide (Y₂O₃), strontium titanate (SrTiO₃) and the like are preferable. These materials are extremely low in reactivity with the superconductive layer 9, and will not deteriorate the superconductive property of the superconductive layer 9 even at the boundary surface in contact with the superconductive layer 9.

The superconductive material used in the superconductive layer 9 is not particularly limited, but a yttrium-based oxide superconductor is preferable. The yttrium-based oxide superconductor may be represented by using a chemical formula of YBa₂Cu₃Oₓ. Alternatively, it is acceptable to use a RE-123-based oxide superconductor. The Re-123-based oxide superconductor may be represented by using a chemical formula of REBa₂Cu₃O_{y} (y=6 to 8, and preferably 6.8 to 7, RE represents any rare earth element such as yttrium, Gd, Sm or Ho).

The stabilization layer 10 is formed on one main surface of the superconductive layer 9 opposite to the main surface facing the intermediate layer 8, and the stabilization layer 6 is formed on one main surface of the substrate 7 opposite to the main surface facing the intermediate layer 8. The stabilization layers 6 and 10 are made of any metal material with good conductivity. As the metal material for forming each of the stabilization layers 6 and 10, for example, silver (Ag) or silver alloy is preferable. When the superconductive layer 9 changes from the superconductive state to the normal conductive state, the stabilization layers 6 and 10 each functions as a bypass to bypass the current flowing through the superconductive layer 9.

One main surface of the stabilization layer 10 opposite to the main surface facing the superconductive layer 9 constitutes the main surface 5A, and one main surface of the stabilization layer 6 opposite to the main surface facing the substrate 7 constitutes the main surface 5B. The stabilization layers may be arranged to cover not only the main surface of the laminate composed of the substrate 7, the intermediate layer 8 and the superconductive layer 9 but also the outer periphery of the laminate.

Referring again to FIG. 4, the superconductive wire core 11 is formed by laminating two superconductive members 5 having a structure illustrated in FIG. 6. As illustrated in FIG. 6, the two superconductive members 5 may be laminated in such a manner that the main surface 5B of one superconductive member 5 faces the main surface 5A of the other superconductive member 5, but it is also acceptable that the two superconductive members 5 is laminated in such a manner that the main surface 5B of one superconductive member 5 faces the main surface 5B of the other superconductive member 5.

The first heat dissipation member 12a is disposed on the first main surface 11A of the superconductive wire core 11, in other words, on the main surface 5A of the superconductive member 5. The first heat dissipation member 12a is made of a material having high thermal conductivity. As the material for the first heat dissipation member 12a, any metal material such as SUS, copper (Cu) and aluminum (Al) or any resin having good heat conductivity may be used.

The first heat dissipation member 12a includes, for example, a corrugated plate structure in which a plurality of ridges and a plurality of valleys each extend along the width direction (X direction) of the superconductive wire core 11. The valley of the corrugated plate structure in the first heat dissipation member 12a is connected to the first main surface 11A at each connection location (first connection location) between the first heat dissipation member 12a and the superconductive wire core 11. In other words, the first connection location is formed at plural positions lined up along the longitudinal direction (Z direction) of the superconductive wire core 11.

The first heat dissipation member 12a and the first main surface 11A are bonded to each other by using a conductive bonding agent such as solder or a conductive adhesive. Thereby, a conductive connection layer 14a is formed at each connection location between the first heat dissipation member 12a and the first main surface 11A. When the first heat dissipation member 12a and the superconductive wire core 11 are bonded to each other by using a solder containing for example bismuth (Bi) and tin (Sn) as the components, silver contained in the stabilizing layer 6 constituting the main surface 5A of the superconductive member 5 reacts with bismuth and tin contained in the solder and forms a solder layer containing an Sn—Bi—Ag based alloy as a component at the connection location between the first heat dissipation member 12a and the first main surface 11A.

The second heat dissipation member 12b is disposed on the second main surface 11B of the superconductive wire core 11, in other words, on the main surface 5A of the main body 5. The second heat dissipation member 12b is made of the same material as the first heat dissipation member 12a.

The second heat dissipation member 12b includes a corrugated plate structure similar to the corrugated plate structure in the first heat dissipation member 12a. The ridge of the corrugated plate structure in the second heat dissipation member 12b is connected to the second main surface 11B at each connection location (second connection location) between the second heat dissipation member 12b and the superconductive wire core 11. In other words, the second connection location is formed at plural positions lined up along the longitudinal direction (Z direction) of the superconductive wire core 11.

A conductive connection layer 14a is formed at each connection location between the second heat dissipation member 12b and the second main surface 11B. Similar to the connection layer 14a, the connection layer 14b is a solder layer containing an Sn—Bi—Ag based alloy as a component, for example.

As described above, since the heat dissipation members 12a and 12b are connected to the first main surface 11A and the second main surface 11B, respectively, the heat generated in the superconductive wire core 11 during the current limiting operation is dissipated to the coolant 34 through the heat dissipation members 12a and 12b.

Specifically, after the superconductive wire core 11 becomes electrically resistant, and a current flows therethrough at this time, the temperature of the superconductive wire core 11 rises rapidly. Affected by the temperature rise, the temperature of the coolant 34 surrounding the superconductive wire core 11 also rise rapidly, and consequently, the coolant 34 vaporizes (boils).

In the present disclosure, since the heat dissipation members 12a and 12b are formed on the main surfaces 11A and 11B of the superconductive wire core 11, respectively, it is possible to prevent the boiling state of the coolant 34 on the surface of the superconductive wire core 11 to change from the nucleate boiling state to the film boiling state. It is considered that the reason should be that the presence of the heat dissipation members 12a and 12b at the contact boundary to the coolant 34 makes it difficult for the coolant 34 which is evaporated from the surface of the superconductive wire core 11 to continue to cover the surface of the superconductive member 11 (it is difficult for a gas layer of the evaporated coolant 34 to cover the surface of the superconductive wire core 11). Thus, in comparison with the case where the film boiling occurs in the coolant 34, it is possible to dissipate heat from the superconductive wire core 11 to the coolant 34 more efficiently.

On the other hand, as described above, since the connection layers 14a and 14b each is electrically conductive, the resistance components in each of the connection layers 14a and 14b are electrically connected in parallel to form a circuit structure substantially equivalent to the superconductive member 5 at the connection location between the heat dissipation members 12a, 12b and the superconductive member 5. Therefore, as the superconductive member 5 is shifted to the normal conductive state, the electrical resistance at the connection location is lower than the electrical resistance at any position other than the connection location. Accordingly, when a current flows in the longitudinal direction (Z direction) of the superconductive member 5, the amount of heat generated at the connection location is relatively smaller than the amount of heat generated at any position other than the connection location. As a result, in the superconductive member 5, a region (a region 20 in the figure) in which the temperature rise is relatively small and a region (a region 22 in the figure) in which the temperature rise is relatively large are formed alternatively along the longitudinal direction (Z direction), which causes an irregular temperature distribution to occur in the superconductive member 5.

When viewed from the thickness direction (Y direction) of the superconductive wire 2, in other words, when viewed from a direction perpendicular to the main surface of the superconductive wire 2, if each connection location (first connection location) between the first heat dissipation member 12a and the first main surface 11B and a corresponding connection location (second connection location) between the second heat dissipation member 12b and the second main surface 11B are arranged so as to overlap each other, in the two laminated superconductive members 5, the regions having a relatively small temperature rise become closer to each other, and the regions having a relatively large temperature rise become closer to each other. As a result, the irregular temperature distribution in the entire superconductive wire core 11 becomes greater. Since it is impossible to cool down the entire superconductive wire core 11 uniformly and efficiently, a longer time is needed to restore the superconductive unit 1 back to the superconductive state. In addition, a local temperature rise may occur in the superconductive wire core 11, which may damage the superconductive wire core 11 by overheat. In order to prevent such damage, the current capacity of the superconductive wire core 11 has to be limited, which contradicts to the original purpose.

In this regard, in the superconductive wire 2 according to the first embodiment, when viewed from the width direction (the direction perpendicular to the main surface of the superconductive wire 2), each connection location (first connection location) between the first heat dissipation member 12a and the first main surface 11A is arranged with an offset from a corresponding connection location (second connection location) between the second heat dissipation member 12b and the second main surface 11B.

Specifically, as illustrated in FIG. 4, each connection location (first connection location) between the first heat dissipation member 12a and the first main surface 11A and a corresponding connection location (second connection location) between the second heat dissipation member 12b and the second main surface 11B are arranged with an offset from each other in the longitudinal direction (Z direction) of the superconductive wire 2.

According to such configuration, as illustrated in FIG. 4, in one of the superconductive members 5 to which the first heat dissipation member 12a is connected and in the other superconductive member 5 to which the second heat dissipation member 12b is connected, a region (a region 20 in the figure) in which the temperature rise is relatively small and a region (a region 22 in the figure) in which the temperature rise is relatively large are formed to face each other. Thereby, the irregular temperature distribution in the entire superconductive wire core 11 is reduced, which makes it possible to suppress the local temperature rise in the superconductive wire core 11. Since it is possible to cool down the superconductive wire core 11 uniformly and efficiently, the superconductive unit 1 may be quickly restored to the superconductive state.

The abovementioned description that “the first connection location and the second connection location are arranged with an offset from each other in the longitudinal direction of the superconductive wire 2” means that in the planar view from the thickness direction, when a distance between two of the adjacent first connection locations in the longitudinal direction is denoted by P (see FIG. 5), the second connection location is disposed at a position less than P/2 (=P×50%) from the middle point of each of the two adjacent first connection locations. In order to reduce the irregular temperature distribution in the superconductive wire 11, the distance between the middle point and the second connection location is preferably 0.4P (=P×40%), and more preferably is 0.3P (=P×30%) or less.

### First Modification of First Embodiment

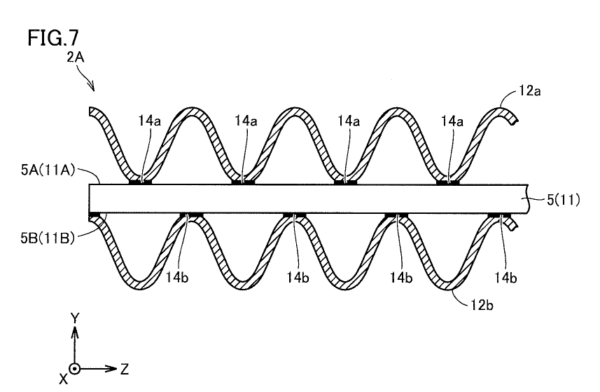

FIG. 7 is a schematic cross-sectional view illustrating the structure of a superconductive wire 2A according to a first modification of the first embodiment. The cross section illustrated in FIG. 7 is cut along the extending direction of the superconductive wire 2A. The superconductive wire 2A according to the first modification is basically similar in structure to the superconductive wire 2 illustrated in FIG. 4, but is different from the superconductive wire 2 in that the superconductive wire core 11 is formed of a single superconductive member 5.

In other words, in the superconductive wire 2A, the main surface 5A of the superconductive member 5 constitutes the first main surface 11A of the superconductive wire core 11, and the main surface 5B of the superconductive member 5 constitutes the second main surface 11B of the superconductive wire core 11. The first heat dissipation member 12a is disposed on the main surface 5A of the superconductive member 5, and the second heat dissipation member 12b is disposed on the main surface 5B of the superconductive member 5.

As illustrated in FIG. 7, in the planar view from the width direction (Y direction), each connection location (first connection location) between the first heat dissipation member 12a and the main surface 5A and a corresponding connection location (second connection location) between the second heat dissipation member 12b and the main surface 5B are arranged with an offset from each other in the longitudinal direction (Z direction) of the superconductive wire 2A. Thereby, the irregular temperature distribution in the entire superconductive wire core 11 (the superconductive member 5) may be reduced. As a result, it is possible to obtain the same effects as the superconductive wire 2 illustrated in each of FIG. 4.

### Second Modification of First Embodiment

FIG. 8 is a schematic cross-sectional view illustrating the structure of a superconductive wire 2B according to a second modification of the first embodiment. The cross section illustrated in FIG. 8 is cut along the extending direction of the superconductive wire 2B. The superconductive wire 2B according to the second modification is basically similar in structure to the superconductive wire 2 illustrated in FIG. 4, but is different from the superconductive wire 2 in the structure of the heat dissipation members 12a and 12b.

Specifically, the first heat dissipation member 12a is formed by arranging a plurality of first plate-shaped members 15a extending in the width direction (X direction) of the superconductive wire core 11 on the first main surface 11A with an interval present therebetween along the longitudinal direction (Z direction). Thus, each of the plurality of first plate-shaped members 15a is connected to the first main surface 11A at a corresponding connection location (first connection location) between the first heat dissipation member 12a and the first main surface 11A. A conductive connection layer 14a is formed at the connection location between each of the plurality of first plate-shaped members 15a and the first main surface 11A.

The second heat dissipation member 12b is formed by arranging a plurality of second plate-shaped members 15b extending in the width direction (X direction) of the superconductive wire core 11 on the second main surface 11B with an interval present therebetween along the longitudinal direction (Z direction). Thus, each of the plurality of second plate-shaped members 15b is connected to the second main surface 11B at a corresponding connection location (second connection location) between the second heat dissipation member 12b and the second main surface 11B. A conductive connection layer 14b is formed at the connection location between each of the plurality of second plate-shaped members 15b and the second main surface 11B.

The plate-shaped members 15a and 15b each is made of a material having high thermal conductivity. As the material for the plate-shaped members 15a and 15b, any metal material such as SUS, copper (Cu) and aluminum (Al) or any resin having good heat conductivity may be used.

As illustrated in FIG. 8, similar to the superconductive wire 2 illustrated in FIG. 4, in the superconductive wire 2B, each connection location (first connection location) between the first heat dissipation member 12a and the first main surface 11A and a corresponding connection location (second connection location) between the second heat dissipation member 12b and the second main surface 11B are arranged with an offset from each other in the longitudinal direction (Z direction) of the superconductive wire 2. In other words, in the planar view from the thickness direction, when the distance between two of the adjacent first connection locations in the longitudinal direction is denoted by P (see FIG. 5), the second connection location is disposed at a position less than P/2 from the middle point of each of the two adjacent first connection locations. In the planar view, the distance between the second connection location and the middle point is preferably 0.4P or less, and more preferably is 0.3P or less. As a result, it is possible to obtain the same effects as the superconductive wire 2 illustrated in each of FIG. 4.

### Second Embodiment

FIG. 9 is a schematic perspective view illustrating the structure of a superconductive wire 2C according to a second embodiment. The superconductive wire 2C according to the second embodiment is basically similar in structure to the superconductive wire 2 illustrated in FIG. 4, but is different from the superconductive wire 2 in the structure of the heat dissipation members 12a and 12b

Specifically, as illustrated in FIG. 9, in the superconductive wire 2C, the first heat dissipation member 12a is arranged in a region located at one side of the first main surface 11A of the superconductive wire core 11 in the width direction (X direction). The first heat dissipation member 12a includes, for example, a corrugated plate structure in which a plurality of ridges and a plurality of valleys each extend along the width direction of the superconductive wire core 11. The length of the first heat dissipation member 12a in the width direction thereof is less than the length of the superconductive wire core 11 in the width direction thereof. Preferably, the length of the first heat dissipation member 12a in the width direction thereof is equal to or less than ½ of the length of the superconductive wire core 11 in the width direction thereof. Each of the plurality of valleys of the corrugated plate structure in the first heat dissipation member 12a is connected to the first main surface 11A at a corresponding connection location (first connection location) between the first heat dissipation member 12a and the superconductive wire core 11. The first connection location is formed at plural positions lined up along the longitudinal direction (Z direction) of the superconductive wire core 11. A conductive connection layer 14a is formed at each connection location between the first heat dissipation member 12a and the first main surface 11A.

The second heat dissipation member 12b is arranged in a region located at the other side of the second main surface 11B in the width direction (X direction) which is opposite to the region located at one side of the first main surface 11A of the superconductive wire core 11 in the width direction. The second heat dissipation member 12b includes, for example, a corrugated plate structure in which a plurality of ridges and a plurality of valleys each extend along the width direction of the superconductive wire core 11. The length of the second heat dissipation member 12b in the width direction thereof is less than the length of the superconductive wire core 11 in the width direction thereof. Preferably, the length of the second heat dissipation member 12b in the width direction thereof is equal to or less than ½ of the length of the superconductive wire core 11 in the width direction thereof. Each of the plurality of valleys of the corrugated plate structure in the second heat dissipation member 12b is connected to the second main surface 11B at a corresponding connection location (second connection location) between the second heat dissipation member 12b and the superconductive wire core 11. The second connection location is formed at plural positions lined up along the longitudinal direction (Z direction) of the superconductive wire core 11. A conductive connection layer 14b is formed at each connection location between the second heat dissipation member 12b and the first main surface 11B.

According to the configuration of the heat dissipation members 12a, 12b as described above, in the superconductive wire 2C of the second embodiment, in the planar view from the thickness direction (Y direction), each connection location (first connection location) between the first heat dissipation member 12a and the first main surface 11A and a corresponding connection location (second connection location) between the second heat dissipation member 12b and the second main surface 11B are arranged with an offset from each other in the width direction of the superconductive wire 2C.

As described in the first embodiment, since a conductive connection layer is formed at each connection location between the heat dissipation member and the superconductive wire core 11, when a current flows through the superconductive wire core 11, the temperature rise in each connection location is relatively smaller than that in another connection location other than the connection location. Thus, in the superconductive wire 2C, the regions in which the temperature rise is relatively small are formed with an offset from each other in the width direction (X direction) between one of the superconductive members 5 to which the first heat dissipation member 12a is connected and the other superconductive member 5 to which the second heat dissipation member 12b is connected. Thereby, the irregular temperature distribution in the entire superconductive wire core 11 is reduced, which makes it possible to suppress the local temperature rise in the superconductive wire core 11. Since it is possible to cool down the superconductive wire core 11 uniformly and efficiently, the superconductive unit 1 may be quickly restored to the superconductive state.

Furthermore, in the superconductive wire 2C according to the second embodiment, in comparison with the superconductive wire 2 illustrated in FIG. 4, since the length of each of the heat dissipation members 12a and 12b in the width direction (X direction) thereof is shortened, the length of each of the connection layers 14a and 14b in the width direction is also shortened accordingly. As a result, the total area of the connection layer formed on the main surface of the superconductive wire core 11 is made smaller than the total area of the connection layer in the superconductive wire 2. Thereby, in the superconductive wire 2C, it is possible to prevent the electrical resistance of the heat dissipation member 11 from becoming smaller due to the formation of the connection layer between the superconductive wire core 11 and the heat dissipation member.

According to the superconductive wire 2C of the second embodiment, when the superconductive wire 2C is wound to form a superconductive coil, the length of the superconductive coil in the radial direction may be shortened in comparison with a superconductive coil which is formed by winding the superconductive wire 2, which will be described hereinafter.

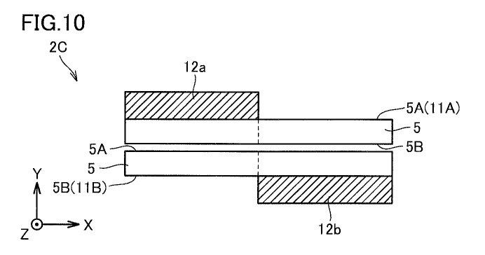

FIG. 10 is a schematic cross-sectional view illustrating the structure of the superconductive wire illustrated in FIG. 9. The cross section illustrated in FIG. 10 is cut along a direction perpendicular to the longitudinal direction (Z direction) of the superconductive wire 2C. As illustrated in FIG. 10, the first heat dissipation member 12a is disposed in a region located at one side of the first main surface 11A of the superconductive wire core 11 in the width direction, and the second heat dissipation member 12b is disposed in a region located at the other side of the second main surface 11B of the superconductive wire core 11 in the width direction. Therefore, when a superconductive coil (see FIG. 3) is formed by winding the superconductive wire 2C, for two of the superconductive wires 2C adjacent to each other in the radial direction of the superconductive coil, the first heat dissipation member 12a in one superconductive wire 2C and the second heat dissipation member 12b in the other superconductive wire 2C are arranged side by side along the direction of the winding shaft (the winding shaft Aa in FIG. 3) of the superconductive coil. In other words, in the planar view from the winding shaft direction of the superconductive coil, the first heat dissipation member 12a and the second heat dissipation member 12b overlap with each other in the radial direction of the superconductive coil. Thereby, when the superconductive coil is formed by winding the superconductive wire which is formed by arranging the heat dissipation members on both main surfaces of the superconductive wire core 11, it is possible to prevent the superconductive coil from becoming larger in the radial direction due to the thickness of the heat dissipation member.

### First Modification of Second Embodiment

FIG. 11 is a schematic perspective view illustrating the structure of a superconductive wire 2D according to a first modification of the second embodiment. The superconductive wire 2D according to the first modification is basically similar in structure to the superconductive wire 2C illustrated in FIG. 9, but is different from the superconductive wire 2C in the configuration of the heat dissipation members 12a and 12b.

Specifically, the first heat dissipation member 12a is formed by arranging a plurality of first plate-shaped members 15a extending in the width direction (X direction) of the superconductive wire core 11 on the first main surface 11A with an interval present therebetween along the longitudinal direction (Z direction). The length of each of the plurality of first plate-shaped members 15a in the width direction thereof is less than the length of the superconductive wire core 11 in the width direction thereof. Preferably, the length of each of the plurality of first plate-shaped members 15a in the width direction thereof is equal to or less than ½ of the length of the superconductive wire core 11 in the width direction thereof. Each of the plurality of first plate-shaped members 15a is connected to the first main surface 11A at a corresponding connection location (first connection location) between the first heat dissipation member 12a and the superconductive wire core 11. A conductive connection layer 14a is formed at each connection location between the plurality of first plate-shaped members 15a and the first main surface 11A.

The second heat dissipation member 12b is formed by arranging a plurality of second plate-shaped members 15b extending in the width direction (X direction) of the superconductive wire core 11 on the second main surface 11B with an interval present therebetween along the longitudinal direction (Z direction). The length of each of the plurality of second plate-shaped members 15b in the width direction thereof is less than the length of the superconductive wire core 11 in the width direction thereof. Preferably, the length of each of the plurality of second plate-shaped members 15b in the width direction thereof is equal to or less than ½ of the length of the superconductive wire core 11 in the width direction thereof. Each of the plurality of second plate-shaped members 15b is connected to the second main surface 11B at a corresponding connection location (second connection location) between the second heat dissipation member 12b and the superconductive wire core 11. A conductive connection layer 14b is formed at each connection location between the plurality of second plate-shaped members 15b and the first main surface 11A.

For the superconductive wire 2D illustrated in FIG. 11, similar to the superconductive wire 2C illustrated in FIG. 9, in the planar view, each connection location (first connection location) between the first heat dissipation member 12a and the first main surface 11A and a corresponding connection location (second connection location) between the second heat dissipation member 12b and the second main surface 11B are arranged with an offset from each other in the width direction of the superconductive wire 2. Thereby, the same effect as that of the superconductive wire 2C illustrated in FIG. 9 may be obtained.

### Second Modification of Second Embodiment

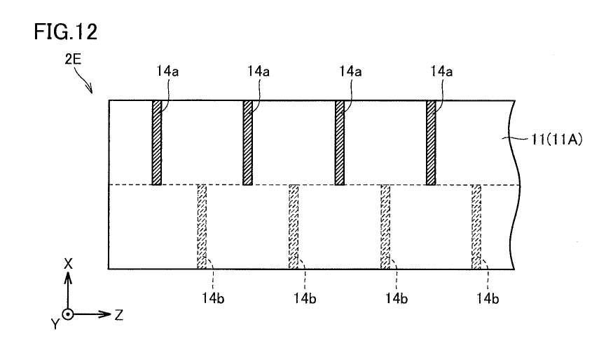

FIG. 12 is a schematic planar view illustrating a superconductive wire 2E according to a second modification of the second embodiment. The superconductive wire 2E according to the second modification is basically similar in structure to the superconductive wire 2C illustrated in FIG. 9, but is different from the superconductive wire 2B in the connection locations between the heat dissipation members 12a, 12b and the superconductive wire core 11. For the sake of clarity and convenience, in FIG. 12, the heat dissipation members 12a and 12b are not illustrated, and only the connection layers 14a and 14b are illustrated to denote the connection locations between the heat dissipation members 12a, 12b and the superconductive wire core 11.

In the superconductive wire 2E illustrated in FIG. 12, in the planar view from the thickness direction (Y direction), each connection location (first connection location) between the first heat dissipation member 12a and the first main surface 11A and a corresponding connection location (second connection location) between the second heat dissipation member 12b and the second main surface 11B are arranged with an offset from each other in both the width direction (X direction) of the superconductive wire 2E and the longitudinal direction (Z direction) of the superconductive wire 2E. Thereby, in comparison with the superconductive wire 2C according to the second embodiment, the regions in which the temperature rise is relatively small are further dispersed in the superconductive wire core. Thus, it is possible to reduce the irregular temperature distribution in the entire superconductive wire core 11, making it possible to obtain the same effect as that of the superconductive wire 2C according to the second embodiment.

### Third Embodiment

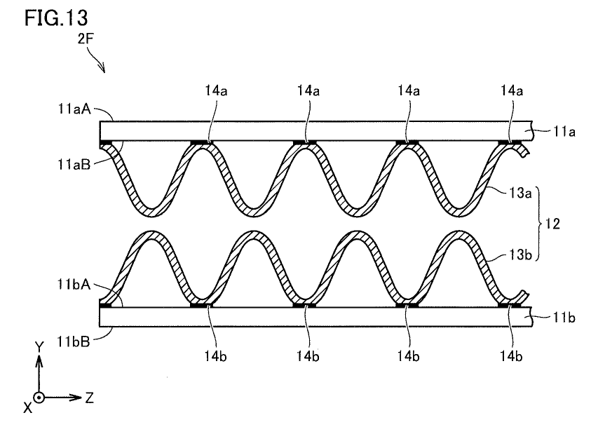

FIG. 13 is a schematic cross-sectional view illustrating the structure of a superconductive wire 2F according to a third embodiment. The cross section illustrated in FIG. 13 is cut along the extending direction of the superconductive wire 2F. Thus, the lateral direction of the paper is taken as the longitudinal direction (Z direction) of the superconductive wire 2F, and the current flows along the lateral direction of the paper.

The superconductive wire 2F according to the third embodiment is basically similar in structure to the superconductive wire 2 illustrated in FIG. 4, but is different from the superconductive wire 2 in that the superconductive wire 2F is provided with two superconductive wire cores 11a, 11b and the heat dissipation member 12 is disposed between the two superconductive wire cores 11a and 11b.

As illustrated in FIG. 13, each of the superconductive wire cores 11a and 11b is formed into a tape shape having a rectangular cross section, and the relatively large surface extending in the longitudinal direction of the tape shape is defined as the main surface. The first superconductive wire core 11a includes a first main surface 11aA and a second main surface 11aB located on the side opposite to the first main surface 11aA. The second superconductive wire core 11b includes a third main surface 11bA and a fourth main surface 11bB located on the side opposite to the third main surface 11bA. The first superconductive wire core 11a and the second superconductive wire core 11b are laminated in such a manner that the second main surface 11aB and the third main surface 11bA are arranged facing each other with an interval present therebetween.

Each of the superconductive wire cores 11a and 11b is formed from the superconductive member 5 (see FIG. 5) having a main surface extending in the longitudinal direction (Z direction). The superconductive member 5 used to form each of the superconductive wire cores 11a and 11b may be 1 or at least 2. The first superconductive wire core 11a and the second superconductive wire core 11b may be formed by using different numbers of the superconductive members 5. When the superconductive wire core 11 is formed by laminating a plurality of superconductive members 5, the main surfaces of the adjacent superconductive members 5 facing each other may be joined to each other directly, or may be bonded to each other by using a conductive bonding agent, or may be bonded to each other by using a bonder made of an electrically insulating material.

The heat dissipation member 12 is disposed between the first superconductive wire core 11a and the second superconductive wire core 11b, and is connected to the second main surface 11aB and the third main surface 11bA, respectively.

The heat dissipation member 12 includes a first heat dissipation component 13a and a second heat dissipation component 13b. The first heat dissipation component 13a is disposed on the second main surface 11aB of the first superconductive wire core 11a. The first heat dissipation component 13a is made of a material having high thermal conductivity. As the material for the first heat dissipation component 13a, any metal material such as SUS, copper (Cu) and aluminum (Al) or any resin having good heat conductivity may be used.

The first heat dissipation component 13a includes, for example, a corrugated plate structure in which a plurality of ridges and a plurality of valleys each extend along the width direction (X direction) of the first superconductive wire core 11a. The ridge of the corrugated plate structure in the first heat dissipation component 13a is connected to the second main surface 11aB at a corresponding connection location (first connection location) between the first heat dissipation component 13a and the first superconductive wire core 11a. The first connection location is formed at plural positions lined up along the longitudinal direction (Z direction) of the first superconductive wire core 11a.

The first heat dissipation component 13a and the second main surface 11aB are bonded to each other by using a conductive bonding material such as a solder or a conductive adhesive. Thereby, a conductive connection layer 14a is formed at each connection location between the first heat dissipation component 13a and the second main surface 11aB. The connection layer 14a may be a solder layer containing, for example, an Sn—Bi—Ag as a component.

The second heat dissipation component 13b is disposed on the third main surface 11bA of the second superconductive wire core 11. The second heat dissipation component 13b is made of the same material as the first heat dissipation component 13a.

The second heat dissipation component 13b includes a corrugated plate structure similar to that included in the first heat dissipation component 13a. The valley of the corrugated plate structure in the second heat dissipation component 13b is connected to the third main surface 11bA at each connection location (second connection location) between the second heat dissipation component 13b and the second superconductive wire core 11b. The second connection location is formed at plural positions lined up along the longitudinal direction (Z direction) of the second superconductive wire core 11b.

A conductive connection layer 14b is formed at each connection location between the second heat dissipation component 13 and the third main surface 11bA. Similar to the connection layer 14a, the conductive connection layer 14b may also be a solder layer containing, for example, an Sn—Bi—Ag as a component.

The first heat dissipation component 13a and the second heat dissipation component 13b are arranged to face each other with an interval present therebetween so as not to overlap with each other. For example, as illustrated in FIG. 13, in the planar view from the thickness direction (Y direction), in other words, a direction perpendicular to the main surface of the superconductive wire 2F, each connection location (first connection location) between the first heat dissipation component 13a and the second main surface 11aB and a corresponding connection location (second connection location) between the second heat dissipation component 13b and the third main surface 11bA are arranged to overlap with each other. In this case, the valley of the corrugated plate structure in the first heat dissipation component 13a and the ridge of the corrugated plate structure in the second heat dissipation component 13b may be arranged to contact each other.

As described above, by connecting the heat dissipation member 12 (heat dissipation components 13a and 13b) between the second main surface 11aB of the first superconductive wire core 11a and the third main surface 11bA of the second superconductive wire core 11b, it is possible to prevent the boiling state of the coolant to change from the nucleate boiling state to the film boiling state due to the rapid temperature rise of the first superconductive wire core 11a and the second superconductive wire core 11b during the current limiting operation. Thereby, the heat generated at each of the first superconductive wire core 11a and the second superconductive wire core 11b is efficiently dissipated to the coolant through the dissipation components 13a and 13b. As a result, it is possible to prevent the cooling time of the superconductive unit 1 from becoming longer due to the increase in the current capacity of the superconductive wire core.

### First Modification of Third Embodiment

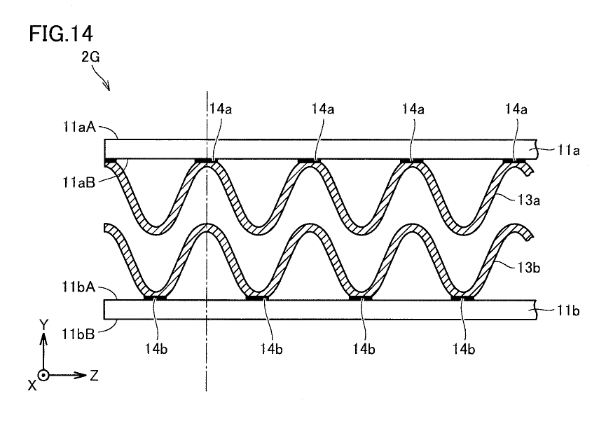

FIG. 14 is a schematic cross-sectional view illustrating the structure of a superconductive wire 2G according to a first modification of the third embodiment. The cross section illustrated in FIG. 14 is cut along the extending direction of the superconductive wire 2G. Thus, the lateral direction of the paper is taken as the longitudinal direction (Z direction) of the superconductive wire 2G, and the current flows along the lateral direction of the paper.

The superconductive wire 2G according to the first modification is basically similar in structure to the superconductive wire 2F illustrated in FIG. 13, but is different from the superconductive wire 2F in the connection locations between the heat dissipation components 13a, 13b and the superconductive wire cores 11a, 11b.

As illustrated in FIG. 14, in the planar view from the thickness direction (Y direction), in other words, from a direction perpendicular to the main surface, each connection location (first connection location) between the first heat dissipation component 13a and the second main surface 11aB and a corresponding connection location (second connection location) between the second heat dissipation component 13b and the third main surface 11bA are arranged with an offset from each other in the longitudinal direction (Z direction) of the superconductive wire 2G. In the example of FIG. 14, the ridges of the corrugated plate structure in the heat dissipation component 13a overlap with the ridges of the corrugated plate structure in the second heat dissipation component 13b, and the valleys of the corrugated plate structure in the heat dissipation component 13a overlap with the valleys of the corrugated plate structure in the second heat dissipation component 13b.

In comparison with the superconductive wire 2F illustrated in FIG. 13, in the superconductive wire 2G of the first modification, since the interval between the first superconductive wire core 11a and the second superconductive wire core 11b may be narrowed, the superconductive wire 2G may be made thinner. Thereby, when the superconductive wire 2G is wound to form a superconductive coil, the length of the superconductive coil in the radial direction may be shortened in comparison with a superconductive coil which is formed by winding the superconductive wire 2F.

### Second Modification of Third Embodiment

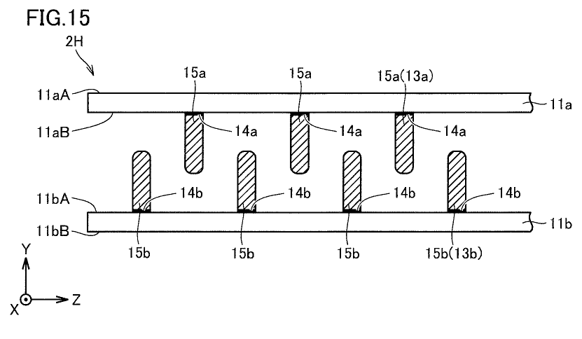

FIG. 15 is a schematic cross-sectional view illustrating the structure of a superconductive wire 2H according to a second modification of the third embodiment. The cross section illustrated in FIG. 15 is cut along the extending direction of the superconductive wire 2H. Thus, the lateral direction of the paper is taken as the longitudinal direction (Z direction) of the superconductive wire 2H, and the current flows along the lateral direction of the paper.

The superconductive wire 2H according to the second modification is basically similar in structure to the superconductive wire 2F illustrated in FIG. 13, but is different from the superconductive wire 2F in the configuration of the heat dissipation components 13a and 13b.

As illustrated in FIG. 15, the first heat dissipation component 13a is formed by arranging a plurality of the plurality of first plate-shaped members 15a extending in the width direction (X direction) of the first superconductive wire core 11a on the second main surface 11aB with an interval present therebetween along the longitudinal direction (Z direction). Thus, each of the plurality of first plate-shaped members 15a is connected to the second main surface 11aB at a corresponding connection location (first connection location) between the first heat dissipation component 13a and the second main surface 11aB. A conductive connection layer 14a is formed at each connection location between each of the plurality of first plate-shaped members 15a and the second main surface 11aB.

The second heat dissipation component 13b is formed by arranging a plurality of the plurality of second plate-shaped members 15b extending in the width direction (X direction) of the second superconductive wire core 11b on the third main surface 11bA with an interval present therebetween along the longitudinal direction (Z direction). Thus, each of the plurality of second plate-shaped members 15b is connected to the third main surface 11bA at a corresponding connection location (second connection location) between the second heat dissipation component 13b and the third main surface 11bA. A conductive connection layer 14b is formed at each connection location between each of the plurality of second plate-shaped members 15b and the third main surface 11bA.

In the superconductive wire 2H illustrated in FIG. 15, similar to the superconductive wire 2G, in the planar view from the thickness direction (Y direction), in other words, from the direction perpendicular to the main surface, each connection location (first connection location) between the first heat dissipation component 13a and the second main surface 11aB and a corresponding connection location (second connection location) between the second heat dissipation component 13b and the third main surface 11bA are arranged with an offset from each other in the longitudinal direction (Z direction) of the superconductive wire 2G. Thus, similar to the superconductive wire 2G illustrated in FIG. 14, the superconductive wire 2H may be made thinner. As a result, the same effect as that of the superconductive wire 2G illustrated in FIG. 14 may be obtained.

In the superconductive wire 2H, the first heat dissipation component 13a may be configured in such a manner that a plurality of first column-shaped members extending in the thickness direction (Y direction) of the superconductive wire 2H may be arranged on the second main surface 11aB to replace the plurality of first plate-shaped members 15a. Similarly, the second heat dissipation component 13b may be configured in such a manner that a plurality of second column-shaped members extending in the thickness direction of the superconductive wire 2H may be arranged on the third main surface 11bA to replace the plurality of second plate-shaped members 15b. The shape of the cross section of each of the first column-shaped members and the shape of the cross section of each of the second column-shaped members in a direction perpendicular to the thickness direction of the superconductive wire 2H may an arbitrary shape such as a polygonal shape including a square shape and a triangle, or a circular shape.

Both the first column-shaped members and the second column-shaped members are lined up with an interval present therebetween along the width direction (X direction) of the superconductive wire 2H and lined up with an interval present therebetween along the longitudinal direction (Z direction) of the superconductive wire 2H, respectively. However, each connection location between the first column-shaped member and the second main surface 11aB is arranged with an offset from a corresponding connection location (second connection location) between the second column-shaped member and the third main surface 11bA in the longitudinal direction or the width direction of the superconductive wire 2H. Thereby, the heat generated in each of the first superconductive wire core 11a and the second superconductive wire core 11b during the current limiting operation may be efficiently dissipated to the coolant through the first column-shaped member and the second column-shaped member. Since the interval between the first superconductive wire core 11a and the second superconductive wire core 11b may be narrowed, the superconductive wire may be made thinner.

### Fourth Embodiment

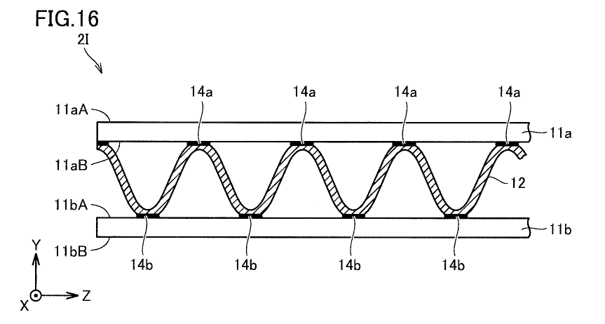

FIG. 16 is a schematic cross-sectional view illustrating the structure of a superconductive wire 2I according to a fourth embodiment. The cross section illustrated in FIG. 16 is cut along the extending direction of the superconductive wire 2I. Thus, the lateral direction of the paper is taken as the longitudinal direction (Z direction) of the superconductive wire 2I, and the current flows along the lateral direction of the paper.

The superconductive wire 2I according to the fourth embodiment is basically similar in structure to the superconductive wire 2F illustrated in FIG. 13, but is different from the superconductive wire 2F in the configuration of the heat dissipation member.

As illustrated in FIG. 16, the heat dissipation member 12 includes, for example, a corrugated plate structure in which a plurality of ridges and a plurality of valleys each extend along the width direction (X direction) of the superconductive wire cores 11a, 11b. The ridge of the corrugated plate structure in the heat dissipation member 12 is connected to the second main surface 11aB at each connection location (first connection location) between the heat dissipation member 12 and the first superconductive wire core 11a. The first connection location is formed at plural positions lined up along the longitudinal direction (Z direction) of the first superconductive wire core 11a. The valley of the corrugated plate structure in the heat dissipation member 12 is connected to the third main surface 11bA at each connection location (second connection location) between the heat dissipation member 12 and the second superconductive wire core 11b. The second connection location is formed at plural positions lined up along the longitudinal direction (Z direction) of the second superconductive wire core 11b.

The heat dissipation member 12 is bonded to both the second main surface 11aB and the third main surface 11bA by using a conductive bonding material such as a solder or a conductive adhesive. Thereby, a conductive connection layer 14a is formed at each connection location between the heat dissipation member 12 and the second main surface 11aB, and a conductive connection layer 14b is formed at each connection location between the heat dissipation member 12 and the third main surface 11bA. Each of the connection layers 14a and 14b may be a solder layer containing, for example, an Sn—Bi—Ag as a component.

As described above, by connecting the heat dissipation member 12 between the second main surface 11aB of the first superconductive wire core 11a and the third main surface 11bA of the second superconductive wire core 11b, the heat generated at each of the first superconductive wire core 11a and the second superconductive wire core 11b is efficiently dissipated to the coolant through the heat dissipation member 12. As a result, it is possible to prevent the cooling time of the superconductive unit from becoming longer due to the increase in the current capacity of the superconductive wire core.

In comparison with the superconductive wire 2F illustrated in FIG. 13, in the superconductive wire 2I of the fourth embodiment, since the interval between the first superconductive wire core 11a and the second superconductive wire core 11b may be narrowed, the superconductive wire 2I may be made thinner. Thereby, when the superconductive wire 2I is wound to form a superconductive coil, the length of the superconductive coil in the radial direction may be shortened in comparison with a superconductive coil which is formed by winding the superconductive wire 2I.

### First Modification of Fourth Embodiment

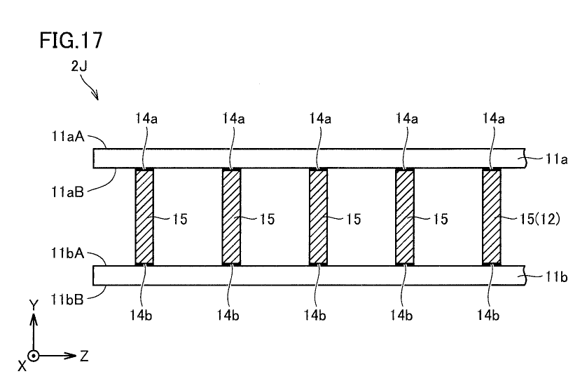

FIG. 17 is a schematic cross-sectional view illustrating the structure of a superconductive wire 2J according to a first modification of the fourth embodiment. The cross section illustrated in FIG. 17 is cut along the extending direction of the superconductive wire 2J. Thus, the lateral direction of the paper is taken as the longitudinal direction (Z direction) of the superconductive wire 2J, and the current flows along the lateral direction of the paper.

The superconductive wire 2J according to the first modification is basically similar in structure to the superconductive wire 2I illustrated in FIG. 16, but is different from the superconductive wire 2I in the configuration of the heat dissipation member 12.

As illustrated in FIG. 17, the heat dissipation member 12 is formed by arranging a plurality of plate-shaped members 15 extending in the width direction (X direction) of the superconductive wire cores 11a and 1 lb with an interval present therebetween along the longitudinal direction (Z direction) between the second main surface 11aB and the third main surface 11bA. Each of the plate-shaped members 15 is bonded to both the second main surface 11aB and the third main surface 11bA by using a conductive bonding material such as a solder or a conductive adhesive. Thereby, a conductive connection layer 14a is formed at each connection location between each of the plate-shaped members 15 and the second main surface 11aB, and a conductive connection layer 14b is formed at each connection location between each of the plate-shaped members 15 and the third main surface 11bA. Each of the connection layers 14a and 14b may be a solder layer containing, for example, an Sn—Bi—Ag as a component.

According to the heat dissipation member 12 having such a structure, the heat generated at each of the first superconductive wire core 11a and the second superconductive wire core 11b may be efficiently dissipated to the coolant through the heat dissipation member 12. As a result, the same effect as that of the superconductive wire 2I illustrated in FIG. 16 may be obtained.

### Second Modification of Fourth Embodiment

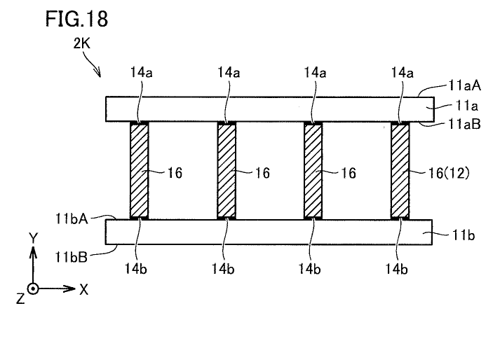

FIG. 18 is a schematic cross-sectional view illustrating the structure of a superconductive wire 2K according to a second modification of the fourth embodiment. The cross section illustrated in FIG. 18 is cut along the extending direction of the superconductive wire 2K. Thus, the lateral direction of the paper is taken as the longitudinal direction (Z direction) of the superconductive wire 2K, and the current flows along the lateral direction of the paper.

The superconductive wire 2K according to the second modification is basically similar in structure to the superconductive wire 2I illustrated in FIG. 16, but is different from the superconductive wire 2I in the configuration of the heat dissipation member 12.

As illustrated in FIG. 18, the heat dissipation member 12 is formed by arranging a plurality of column-shaped members 16 extending in the width direction (X direction) of the superconductive wire cores 11a and 11b between the second main surface 11aB and the third main surface 11bA.

Each of the column-shaped members 16 is made of a material having high thermal conductivity. As the material for each of the column-shaped members 16, any metal material such as SUS, copper (Cu) and aluminum (Al) or any resin having good heat conductivity may be used. The shape of the cross section of each column-shaped member in a direction perpendicular to the thickness direction (Y direction) of the superconductive wire 2K may an arbitrary shape such as a polygonal shape including a square shape and a triangle, or a circular shape.

The column-shaped members 16 are lined up with an interval present therebetween along the width direction (X direction) of the superconductive wire 2K and lined up with an interval present therebetween along the longitudinal direction (Z direction) of the superconductive wire 2K. A conductive connection layer 14a is formed at each connection location between each of the column-shaped members 16 and the second main surface 11aB, and a conductive connection layer 14b is formed at each connection location between each of the plate-shaped members 15 and the third main surface 11bA. Each of the connection layers 14a and 14b may be a solder layer containing, for example, an Sn—Bi—Ag as a component.

According to the heat dissipation member 12 having such a structure, the heat generated at each of the first superconductive wire core 11a and the second superconductive wire core 11b may be efficiently dissipated to the coolant through each of the column-shaped members 16. As a result, the same effect as that of the superconductive wire 2I illustrated in FIG. 16 may be obtained.

In the first to fourth embodiments, a resistance-typed current limiter has been described as an example of the current limiter 100 in which the superconductive wire according to the present disclosure is applied; however, the superconductive wire according to the present disclosure is applicable to a superconductive current limiter of a different type (such as a magnetic shielding current limiter), and is applicable to any current limiter as long as it is such a current limiter that employs superconductive SN transition.

It should be understood that the embodiments disclosed herein have been presented for the purpose of illustration and description but not limited in all aspects. It is intended that the scope of the present invention is not limited to the description above but defined by the scope of the claims and encompasses all modifications equivalent in meaning and scope to the claims.

Supplementary Notes

The following notes are disclosed to further explain the above embodiments.

(Note 1)

Provided is a superconductive wire including:

a first superconductive wire core which has a first main surface extending in the longitudinal direction and a second main surface located on the side opposite to the first main surface and extending in the longitudinal direction;

a second superconductive wire core which has a third main surface extending in the longitudinal direction and a fourth main surface located on the side opposite to the third main surface and extending in the longitudinal direction;

the first superconductive wire core and the second superconductive wire core are laminated in such a manner that the second main surface and the third main surface are arranged facing each other with an interval present therebetween;

the superconductive wire includes a heat dissipation member which is arranged between the first superconductive wire core and the second superconductive wire core and is connected to both the second main surface and the third main surface.

According to the abovementioned configuration, in the current limiter using the superconductive wire, the heat generated in the first superconductive wire core and the second superconductive wire core during the current limiting operation may be efficiently dissipated to the coolant through the dissipation members arranged between the first superconductive wire core and the second superconductive wire core. Thereby, even when the current capacity of the superconductive wire core is increased, it is possible to quickly restore the current limiter to the superconductive state.

(Note 2)

According to the superconductive wire described in note 1, the heat dissipation member includes:

a first heat dissipation component disposed on the second main surface;

a second heat dissipation component disposed on the third main surface;

the first heat dissipation component is connected to the second main surface at a plurality of first connection locations arranged along the longitudinal direction;

the second heat dissipation component is connected to the third main surface at a plurality of second connection locations arranged along the longitudinal direction; and

the first heat dissipation component and the second heat dissipation component are arranged facing each other with an interval present therebetween.

According to the abovementioned configuration, the heat generated in the first superconductive wire core and the second superconductive wire core may be efficiently dissipated to the coolant through the first and second dissipation components arranged between the first superconductive wire core and the second superconductive wire core.

(Note 3)

According to the superconductive wire described in note 2, in the planar view from the thickness direction of the superconductive wire, each of the plurality of first connection locations and a corresponding one of the plurality of second connection locations are arranged with an offset from each other.

According to the abovementioned configuration, since the first heat dissipation component and the second heat dissipation component are arranged between the first and second superconductive wire cores and the interval between the first and second superconductive wire cores may be narrowed, the superconductive wire may be made thinner.

(Note 4)

According to the superconductive wire described in note 3,

each of the first heat dissipation component includes a corrugated plate structure in which a plurality of ridges and a plurality of valleys each extend along the width direction of the first superconductive wire core, and each of the second heat dissipation component includes a corrugated plate structure in which a plurality of ridges and a plurality of valleys each extend along the width direction of the second superconductive wire core,

each of the plurality of ridges of the corrugated plate structure in the first heat dissipation component is connected to the second main surface at a corresponding one of the plurality of first connection locations,

each of the plurality of valleys of the corrugated plate structure in the second heat dissipation component is connected to the third main surface at a corresponding one of the plurality of second connection locations,

in the planar view, the ridges of the corrugated plate structure in the heat dissipation component overlap with the ridges of the corrugated plate structure in the second heat dissipation component, and the valleys of the corrugated plate structure in the heat dissipation component overlap with the valleys of the corrugated plate structure in the second heat dissipation component.

According to the abovementioned configuration, since the first heat dissipation component and the second heat dissipation component, each has a corrugated plate structure, are arranged between the first and second superconductive wire cores and the interval between the first and second superconductive wire cores may be narrowed, the superconductive wire may be made thinner.

(Note 5)

According to the superconductive wire described in note 3,

the first heat dissipation component is formed by arranging a plurality of first plate-shaped members extending in the width direction of the first superconductive wire core on the second main surface with an interval present therebetween along the longitudinal direction, and the second heat dissipation component is formed by arranging a plurality of second plate-shaped members extending in the width direction of the second superconductive wire core on the third main surface with an interval present therebetween along the longitudinal direction,

each of the first plate-shaped member is connected to the second main surface at a corresponding one of the plurality of first connection locations;

each of the second plate-shaped member is connected to the third main surface at a corresponding one of the plurality of second connection locations.

According to the abovementioned configuration, since the first heat dissipation component and the second heat dissipation component, each is formed of a plurality of plate-shaped members, are arranged between the first and second superconductive wire cores and the interval between the first and second superconductive wire cores may be narrowed, the superconductive wire may be made thinner.

(Note 6)

According to the superconductive wire described in note 1,

each of the heat dissipation members includes a corrugated plate structure in which a plurality of ridges and a plurality of valleys each extend along the width direction of the first and second superconductive wire cores,

each of the plurality of ridges of the corrugated plate structure is connected to to the second main surface, and

each of the plurality of valleys of the corrugated plate structure is connected to the third main surface.

According to the abovementioned configuration, by arranging the heat dissipation member having the corrugated plate structure between the first and second superconductive wire cores, the superconductive wire may be made thinner while ensuring the heat dissipation properties thereof.

(Note 7)

According to the superconductive wire described in note 1, the heat dissipation member is formed by arranging a plurality of plate-shaped members extending in the width direction of the first and second superconductive wire cores with an interval present therebetween along the longitudinal direction between the second main surface and the third main surface.

According to the abovementioned configuration, by arranging the heat dissipation member composed of a plurality of plate-shaped members between the first and second superconductive wire cores, the superconductive wire may be made thinner while ensuring the heat dissipation properties thereof.

(Note 8)

According to the superconductive wire described in note 1, the heat dissipation member is formed by arranging a plurality of column-shaped members extending in the width direction of the first and second superconductive wire cores with an interval present therebetween along the longitudinal direction between the second main surface and the third main surface.

According to the abovementioned configuration, by arranging the heat dissipation member composed of a plurality of column-shaped members between the first and second superconductive wire cores, the superconductive wire may be made thinner while ensuring the heat dissipation properties thereof.

(Note 9)

According to the superconductive wire described in any of notes 1 to 8, at least one of the first superconductive wire core and the second superconductive wire core is formed by laminating a plurality of superconductive members, each has a main surface extending in the longitudinal direction, along the normal direction of the main surface.

According to the abovementioned configuration, even when the current capacity of the superconductive wire core is increased, the heat generated in the superconductive wire core during the current limiting operation may be efficiently dissipated to the coolant through the dissipation member, which makes it possible to quickly restore the current limiter to the superconductive state.

(Note 10)

Provided is a current limiter including:

a superconductive unit made of the superconductive wire according to any of notes 1 to 10; and

a coolant container configured to house therein the superconductive unit and coolant for cooling the superconductive unit.

According to the abovementioned configuration, even when the current capacity of the superconductive wire core is increased, it is possible to quickly restore the current limiter to the superconductive state.

### REFERENCE SIGNS LIST

1: superconductive unit; 2, 2A-2K: superconductive wire; 3: parallel resistance unit; 4: conductive wire; 5: superconductive member; 5A, 5B: main surface; 6, 10: stabilization layer; 7: substrate; 8: intermediate layer; 9: superconductive layer; 11: superconductive wire core; 11a: first superconductive wire core; 11b: second superconductive wire core; 11A, 11aA: first main surface; 11B, 11aB: second main surface; 11bA: third main surface, 11bB: fourth main surface; 12: heat dissipation member; 12a: first heat dissipation member; 12b: second heat dissipation member; 13a: first heat dissipation component; 13b: second heat dissipation component; 14a, 14b: connection layer; 15: plate-shaped member; 15a: first plate-shaped member; 15b: second plate-shaped member; 16: column-shaped member; 30: coolant container; 34: coolant; 36: introduction unit; 38: discharge unit; 100: current limiter

1. A superconductive wire comprising:
a superconductive wire core which has a first main surface extending in the longitudinal direction and a second main surface located on the side opposite to the first main surface and extending in the longitudinal direction;
a first heat dissipation member disposed on the first main surface; and
a second heat dissipation member disposed on the second main surface,
the first heat dissipation member being connected to the first main surface at a plurality of first connection locations which are lined up along the longitudinal direction,
the second heat dissipation member being connected to the second main surface at a plurality of second connection locations which are lined up along the longitudinal direction,
in a planar view from the thickness direction of the superconductive wire, each of the plurality of first connection locations and a corresponding one of the plurality of second connection locations are arranged with an offset from each other.

2. The superconductive wire according to claim 1, wherein
in the planar view, each of the plurality of first connection locations and a corresponding one of the plurality of second connection locations are arranged with an offset from each other in the longitudinal direction.

3. The superconductive wire according to claim 2, wherein
the first heat dissipation member and the second heat dissipation member each includes a corrugated plate structure in which a plurality of ridges and a plurality of valleys each extend along the width direction of the superconductive wire core,
each of the plurality of valleys of the corrugated plate structure in the first heat dissipation member is connected to the first main surface at a corresponding one of the plurality of first connection locations,
each of the plurality of ridges of the corrugated plate structure in the second heat dissipation member is connected to the second main surface at a corresponding one of the plurality of second connection locations,
in the planar view, each of the plurality of valleys in the first heat dissipation member is overlapped with a corresponding one of the plurality of valleys in the second heat dissipation member, and each of the plurality of ridges in the first heat dissipation member is overlapped with a corresponding one of the plurality of ridges in the second heat dissipation member.

4. The superconductive wire according to claim 2, wherein
the first heat dissipation member is formed by arranging a plurality of first plate-shaped members extending in the width direction of the superconductive wire core on the first main surface with an interval present therebetween along the longitudinal direction,
the second heat dissipation member is formed by arranging a plurality of second plate-shaped members extending in the width direction of the superconductive wire core on the second main surface with an interval present therebetween along the longitudinal direction,
each of the plurality of first plate-shaped members is connected to the first main surface at a corresponding one of the plurality of first connection locations,
each of the plurality of second plate-shaped members is connected to the second main surface at a corresponding one of the plurality of second connection locations.

5. The superconductive wire according to claim 1, wherein
in the planar view, each of the plurality of first connection locations and a corresponding one of the plurality of second connection locations are arranged with an offset from each other in the width direction of the superconductive wire core.

6. The superconductive wire according to claim 5, wherein
the first heat dissipation member and the second heat dissipation member each includes a corrugated plate structure in which a plurality of ridges and a plurality of valleys each extend along the width direction of the superconductive wire core,
the length of the corrugated plate structure in the width direction thereof is less than the length of the superconductive wire core in the width direction thereof,
each of the plurality of valleys of the corrugated plate structure in the first heat dissipation member is connected to the first main surface at a corresponding one of the plurality of first connection locations in a region located at one side of the first main surface in the width direction,
each of the plurality of ridges of the corrugated plate structure in the second heat dissipation member is connected to the second main surface at a corresponding one of the plurality of second connection locations in a region located at the other side of the second main surface in the width direction which is opposite to the region located at one side of the first main surface in the width direction.

7. The superconductive wire according to claim 5, wherein
the first heat dissipation member is formed by arranging a plurality of first plate-shaped members extending in the width direction of the superconductive wire core on the first main surface with an interval present therebetween along the longitudinal direction,
the second heat dissipation member is formed by arranging a plurality of second plate-shaped members extending in the width direction of the superconductive wire core on the second main surface with an interval present therebetween along the longitudinal direction,
the length of each of the plurality of first plate-shaped members and the length of each of the plurality of second plate-shaped members in the width direction thereof is less than the length of the superconductive wire core in the width direction thereof,
each of the plurality of first plate-shaped members is connected to the first main surface at a corresponding one of the plurality of first connection locations in a region located at one side of the first main surface in the width direction,
each of the plurality of second plate-shaped members is connected to the second main surface at a corresponding one of the plurality of second connection locations in a region located at the other side of the second main surface in the width direction which is opposite to the region located at one side of the first main surface in the width direction.

8. The superconductive wire according to claim 5, wherein
in the planar view, each of the plurality of first connection locations and a corresponding one of the plurality of second connection locations are arranged with an offset from each other in the longitudinal direction.

9. The superconductive wire according to claim 1, wherein
the superconductive wire further includes a conductive connection layer formed between the first heat dissipation member and the superconductive wire core or between the second heat dissipation member and the superconductive wire core at each of the plurality of first connection locations and each of the plurality of second connection locations.

10. The superconductive wire according to claim 1, wherein
the superconductive wire core is formed by laminating a plurality of the superconductive members along the normal direction of the main surface, each of the plurality of the superconductive members having a main surface extending in the longitudinal direction.

11. A current limiter comprising:
a superconductive unit made of the superconductive wire according to claim 1; and
a coolant container configured to house therein the superconductive unit and coolant for cooling the superconductive unit.
